(19) United States
(12) Patent Application Publication
(10) Pub. No.: US 2026/0316188 A1
(43) Pub. Date: Oct. 15, 2026

(54) DUAL-OPTICAL-PATH CUTTING METHOD BASED ON REFRACTION-REFLECTION LASER BEAM COLLECTION SYSTEM

(71) Applicants: Guangdong University of Technology, Guangzhou (CN); Guangdong Longxin Laser Intelligent Equipment Co., Ltd, Foshan (CN)

(72) Inventors: YU DENG, Guangzhou (CN); HAOBIN LAO, Foshan (CN); TINGYIN HUANG, Guangzhou (CN); XUECHAO XIAO, Foshan (CN); ZIHONG CEN, Guangzhou (CN); CHANGBIN JI, Foshan (CN); YUANLE LIANG, Foshan (CN)

(21) Appl. No.: 19/630,558

(22) Filed: Mar. 27, 2026

(30) Foreign Application Priority Data
Apr. 15, 2025 (CN) 202510469527.7

(51) Int. Cl. B23K 26/38; B23K 26/064

(52) U.S. Cl. CPC B23K 26/38; B23K 26/0643; B23K 26/0648

(57) ABSTRACT

The disclosure provides a dual-optical-path cutting method based on a refraction-reflection laser beam collection system, relating to the laser cutting technology field, including: S1, introducing the laser beam within the optical fiber to a starting point of an internal optical path of a laser; S2, guiding the laser beam into an optical element assembly via an optical path reflecting mirror; S3, performing optical path correction on the laser beam by the optical element assembly; S4, performing total reflection collection on a refracted beam and a reflected beam by a total reflection mirror and a semi-enveloping controllable-angle total reflection mirror; S5, adjusting an incident laser beam by the laser beam of a main optical path, causing a focus thereof to act on a workpiece surface; and S6, using the secondary optical path focusing lens to adjust the refraction-reflection laser beam, causing a focus thereof to act on the workpiece surface.

### CROSS-REFERENCE TO RELATED APPLICATION

This application claims priority of Chinese Patent Application No. 202510469527.7, filed on April 15, 2025, the entire contents of which are incorporated herein by reference.

### TECHNICAL FIELD

The present disclosure relates to the field of laser cutting technology, and in particular to a dual-optical-path cutting method based on a refraction-reflection laser beam collection system.

### BACKGROUND

Laser cutting is a high-precision machining technology that utilizes a high-power-density laser beam to irradiate the surface of a material, causing it to rapidly melt, vaporize, or reach its ignition point, and then uses high-pressure auxiliary gas to blow away the molten slag, thereby achieving material separation. The core principle involves a high-energy laser beam generated by a laser, which is focused by an optical system to form a high-power-density spot. After this spot irradiates the surface of a workpiece, the material is rapidly heated to its melting point or vaporization point. The molten or vaporized material is then removed by a high-speed gas flow, achieving high-precision cutting.

In the metal processing industry, laser cutting can precisely cut metallic materials such as carbon steel, stainless steel, aluminum alloy, and copper alloy. It is applied in fields including sheet metal processing, mechanical parts manufacturing, and precision instrument fabrication, enabling the high-precision production of complex parts and improving production efficiency. In the field of automobile manufacturing, laser cutting technology is widely applied in the processing of body structural parts, chassis, exhaust pipes, engine components, and the like. Its high precision and flexible machining capabilities render automobile production more efficient and enable the satisfaction of customized manufacturing requirements. In the aerospace field, laser cutting is widely used for the precision machining of high-strength, difficult-to-process materials such as titanium alloys, aluminum alloys, stainless steel, and composite materials. Applications include aircraft structural parts, engine blades, and satellite components, ensuring the lightweight nature, high strength, and high reliability of the parts. In the electronics and electrical industry, laser cutting can be used for the fabrication of precision circuit boards, semiconductor packaging, and microelectronic devices. This ensures high precision and high efficiency, meeting the demands for miniaturization and high performance in electronic equipment. In the field of medical device manufacturing, laser cutting is used for the fabrication of medical instruments such as scalpels, implants, and stents. This ensures high precision, burr-free edges, and contamination-free surfaces, thereby enhancing the quality and safety of the medical devices. In the architectural decoration industry, laser cutting is used for customized processing of items such as metal curtain walls, carved patterns, and stainless steel decorative components. This allows architectural designs to be more exquisite and complex, while maintaining high processing precision and stability. Additionally, laser cutting is also widely used in industries such as energy equipment manufacturing, rail transportation, shipbuilding, and home appliance manufacturing.

However, in the prior art, lasers are prone to severe heating during continuous processing. The heating of a laser primarily originates from energy conversion losses, thermal effects in the gain medium, heat generated by absorption in optical components, and power losses in electronic devices. To a large extent, the heating problem of a laser is caused by the absorption of laser light due to refraction and reflection by optical components within the laser optical path. At the present stage, the reflectivity of a total reflection mirror inside a laser for laser light can reach 99.5%. However, the transmittance of a lens inside the laser for laser light is only between 80% and 95%. Due to the physical characteristics of lenses, it is currently difficult to improve their performance. This indicates that a significant amount of laser energy is absorbed by the internal components of the laser during processes such as reflection and refraction, causing the temperature of the laser to rise, especially in high-power lasers. This not only wastes laser energy but also has a great impact on the service life of the laser.

Therefore, it is very necessary to provide a dual-optical-path cutting method based on a refraction-reflection laser beam collection system.

### SUMMARY

To solve the above technical problems, the present disclosure provides a dual-optical-path cutting method based on a refraction-reflection laser beam collection system. In the method, by disposing a semi-enveloping controllable-angle total reflection mirror and a total reflection mirror, the laser light reflected and refracted by each lens is collected through the total reflection mirror sheet, improving energy utilization efficiency, reducing the absorption of laser energy by internal components of the laser, and decreasing heat generation. At the same time, the collected laser light is converged and guided to a secondary optical path, and then a surface of a workpiece is pre-treated to reduce reflection from the workpiece surface and increase the energy concentration rate of the main optical path spot, thereby solving the problems mentioned in the background art section.

The dual-optical-path cutting method based on a refraction-reflection laser beam collection system, including a lens, a laser beam, an optical fiber, an optical path reflecting mirror, an optical element assembly, a main optical path, a main optical path focusing lens, and a workpiece, wherein: the lens is disposed on an optical path of the laser beam emitted from the optical fiber; the optical path reflecting mirror is disposed on a side of the lens facing away from the optical fiber; the workpiece is disposed on an optical path of the optical path reflecting mirror; the main optical path focusing lens is installed between the workpiece and the optical path reflecting mirror; the optical element assembly is installed between the optical path reflecting mirror and the main optical path focusing lens; the main optical path is an optical path of the laser beam processed through the lens, the optical path reflecting mirror, the optical element assembly, and the main optical path focusing lens.

The dual-optical-path cutting method based on a refraction-reflection laser beam collection system further includes a secondary optical path, a total reflection mirror, a semi-enveloping controllable-angle total reflection mirror, an angle control mechanism, a controller, and a secondary optical path focusing lens, wherein: the semi-enveloping controllable-angle total reflection mirror is installed on two sides of the main optical path focusing lens; the controller is connected to the semi-enveloping controllable-angle total reflection mirror via the angle control mechanism; a light beam emitted from the semi-enveloping controllable-angle total reflection mirror is reflected by the total reflection mirror onto the secondary optical path focusing lens; the secondary optical path is an optical path of the collected light beam processed through the total reflection mirror and the secondary optical path focusing lens.

Further, the optical element assembly includes a reflecting mirror, a focusing mirror, a half-wave plate, a polarization beam splitter, a timer shutter, a spatial light modulator, and a convex lens; the reflecting mirror, the focusing mirror, the half-wave plate, the polarization beam splitter, the timer shutter, the spatial light modulator, and the convex lens perform optical path correction on the laser beam; the semi-enveloping controllable-angle total reflection mirror and the total reflection mirror are each composed of a plurality of total reflection mirror sheets, and each total reflection mirror sheet is connected to the angle control mechanism.

Further, the semi-enveloping controllable-angle total reflection mirror and the total reflection mirror are each provided with a patch sensor; the patch sensor is connected to the controller.

The dual-optical-path cutting method based on a refraction-reflection laser beam collection system, using the above-described dual-optical-path cutting system based on a refraction-reflection laser beam collection system, including the following steps:

S1, introducing the laser beam within the optical fiber to the starting point of the internal optical path of the laser through the synergistic action of multiple components including a take-up reel, an optical fiber cable tray, a take-up directional reel, and a balancer;

S2, flattening the laser beam into a parallel beam through the action of the lens, and then guiding the flattened laser beam into the optical element assembly via the optical path reflecting mirror;

S3, performing optical path correction on the laser beam by the optical element assembly;

S4, passing the laser beam through a focusing lens via a central opening of the semi-enveloping controllable-angle total reflection mirror; simultaneously, allowing a refracted beam and a reflected beam to pass through a refraction-reflection beam collection optical path composed of a plurality of total reflection mirrors and the semi-enveloping controllable-angle total reflection mirror, so as to perform total reflection collection on the refracted beam and the reflected beam;

S5, adjusting an incident laser beam by the laser beam of a main optical path, causing a focus thereof to act on a surface of a workpiece; and

S6, using the secondary optical path focusing lens to adjust the refraction-reflection laser beam, causing a focus of the refraction-reflection laser beam to act on the surface of the workpiece, and ensuring the focus of the refraction-reflection laser beam is located ahead of the focus of the main optical path laser beam.

Further, in the step S4, when the laser beam passes through the focusing lens, the laser beam undergoes refraction and reflection phenomena, weakening the energy of the laser beam; in the step S4, the patch sensors on the semi-enveloping controllable-angle total reflection mirror and the total reflection mirror detect the incoming beam and output parameters of an incident angle thereof.

Further, in the step S4, based on the detection data from the patch sensors, the controller controls the angle control mechanism to rotate the positions of the semi-enveloping controllable-angle total reflection mirror and the total reflection mirror, thereby focusing the refraction-reflection beam onto the secondary optical path focusing lens; in the step S6, the focus of the secondary optical path is used to pre-treat the workpiece, and the focal energy of the secondary optical path can reach 10%-15% of the focal energy of the main optical path.

Compared with the prior art, the disclosure has the following beneficial effects:

First, according to the present disclosure, by disposing a semi-enveloping controllable-angle total reflection mirror and a total reflection mirror, the laser light reflected and refracted by each lens is collected through the total reflection mirror sheet, thereby improving energy utilization efficiency, reducing absorption of laser energy by internal components of the laser, and decreasing heat generation. Simultaneously, the collected laser light is converged and guided to a secondary optical path to pre-treat a surface of a workpiece, thereby reducing reflection from the workpiece surface and increasing an energy concentration rate of a main optical path spot.

Second, according to the present disclosure, by disposing a controller and a secondary optical path focusing lens, based on detection data from patch sensors, the controller controls an angle control mechanism to rotate positions of a semi-enveloping controllable-angle total reflection mirror and a total reflection mirror, thereby focusing a refraction-reflection beam onto the secondary optical path focusing lens. Then, through the action of the secondary optical path focusing lens, a focus of the refraction-reflection laser beam acts on the workpiece. According to existing lens refraction and reflection performance, focal energy of the secondary optical path can reach about 10%-15% of focal energy of a main optical path. At this time, the focus of the secondary optical path is used to pre-treat the workpiece, causing local melting and surface modification on the surface of the workpiece, increasing surface roughness thereof, reducing reflection of the laser beam during main optical path processing, further increasing absorption of laser beam energy in a processing region, thereby improving material removal rate.

### BRIEF DESCRIPTION OF THE DRAWINGS

FIG. 1 is a schematic structural diagram of the present disclosure.

FIG. 2 is a flow chart of the present disclosure.

In the figures:

111: secondary optical path; 112: total reflection mirror; 113: semi-enveloping controllable-angle total reflection mirror; 114: angle control mechanism; 115: controller; 116: lens; 117: laser beam; 118: optical fiber; 119: optical path reflecting mirror; 1110: optical element assembly; 1111: main optical path; 1112: main optical path focusing lens; 1113: secondary optical path focusing lens; 1114: workpiece.

### DETAILED DESCRIPTION OF THE EMBODIMENTS

The present disclosure is further described below with reference to the accompanying drawings.

Embodiment

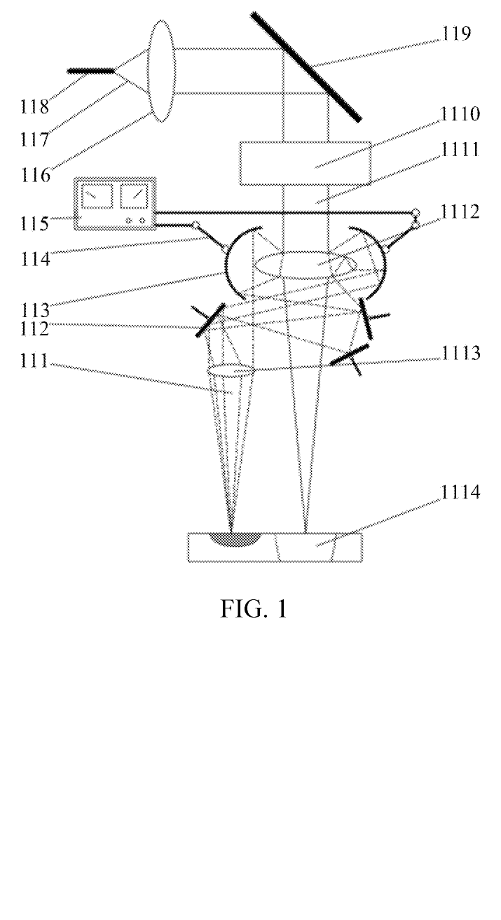

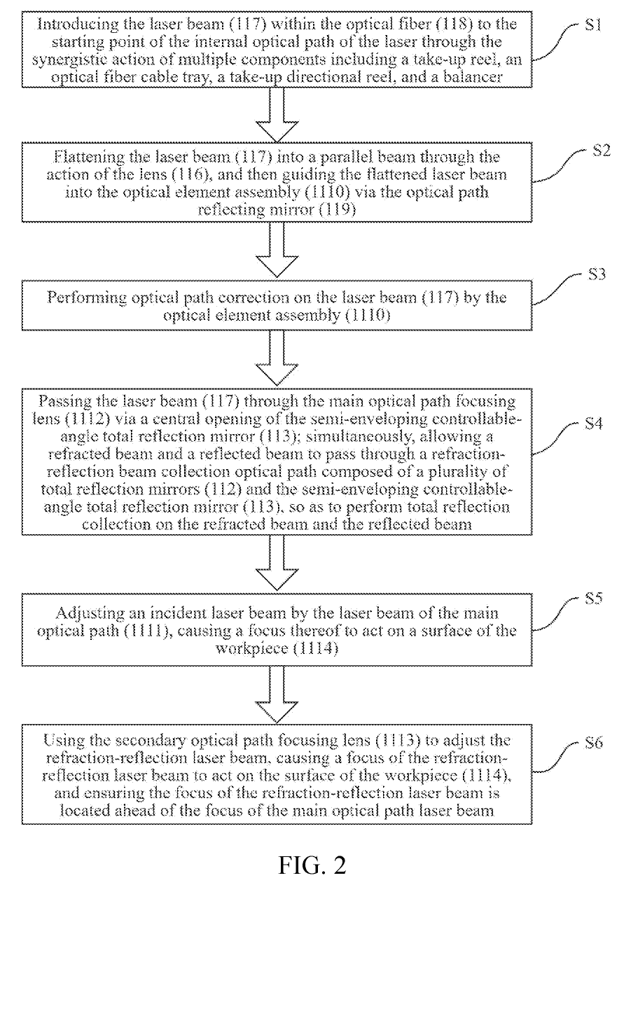

as shown in FIG. 1 and FIG. 2:
the present disclosure provides a dual-optical-path cutting system based on a refraction-reflection laser beam collection system, including a lens 116, a laser beam 117, an optical fiber 118, an optical path reflecting mirror 119, an optical element assembly 1110, a main optical path 1111, a main optical path focusing lens 1112, and a workpiece 1114, wherein: the lens 116 is disposed on an optical path of the laser beam 117 emitted from the optical fiber 118; the optical path reflecting mirror 119 is disposed on a side of the lens 116 facing away from the optical fiber 118; the workpiece 1114 is disposed on an optical path of the optical path reflecting mirror 119; the main optical path focusing lens 1112 is installed between the workpiece 1114 and the optical path reflecting mirror 119; the optical element assembly 1110 is installed between the optical path reflecting mirror 119 and the main optical path focusing lens 1112; the main optical path 1111 is an optical path of the laser beam 117 processed through the lens 116, the optical path reflecting mirror 119, the optical element assembly 1110, and the main optical path focusing lens 1112.

In this embodiment, the dual-optical-path cutting system based on a refraction-reflection laser beam collection system further includes a secondary optical path 111, a total reflection mirror 112, a semi-enveloping controllable-angle total reflection mirror 113, an angle control mechanism 114, a controller 115, and a secondary optical path focusing lens 1113, wherein: the semi-enveloping controllable-angle total reflection mirror 113 is installed on two sides of the main optical path focusing lens 1112; the controller 115 is connected to the semi-enveloping controllable-angle total reflection mirror 113 via the angle control mechanism 114; a light beam emitted from the semi-enveloping controllable-angle total reflection mirror 113 is reflected by the total reflection mirror 112 onto the secondary optical path focusing lens 1113; the secondary optical path 111 is an optical path of the collected light beam processed through the total reflection mirror 112 and the secondary optical path focusing lens 1113.

In this embodiment, the optical element assembly 1110 includes a reflecting mirror, a focusing mirror, a half-wave plate, a polarization beam splitter, a timer shutter, a spatial light modulator, and a convex lens; the reflecting mirror, the focusing mirror, the half-wave plate, the polarization beam splitter, the timer shutter, the spatial light modulator, and the convex lens perform optical path correction on the laser beam 117; the semi-enveloping controllable-angle total reflection mirror 113 and the total reflection mirror 112 are each composed of a plurality of total reflection mirror sheets, and each total reflection mirror sheet is connected to the angle control mechanism 114; the semi-enveloping controllable-angle total reflection mirror 113 and the total reflection mirror 112 are each provided with a patch sensor; the patch sensor is connected to the controller 115; by disposing the semi-enveloping controllable-angle total reflection mirror 113 and the total reflection mirror 112, the laser light reflected and refracted by each lens is collected through the total reflection mirror sheets, thereby improving energy utilization efficiency, reducing absorption of laser energy by internal components of the laser, and decreasing heat generation; simultaneously, the collected laser light is converged and guided to the secondary optical path 111 to pre-treat a surface of the workpiece 1114, thereby reducing reflection from the workpiece surface and increasing an energy concentration rate of a main optical path spot.

A dual-optical-path cutting method based on a refraction-reflection laser beam collection system, using the above-mentioned dual-optical-path cutting system based on a refraction-reflection laser beam collection system, including the following steps:

S1, introducing the laser beam 117 within the optical fiber 118 to the starting point of the internal optical path of the laser through the synergistic action of multiple components including a take-up reel, an optical fiber cable tray, a take-up directional reel, and a balancer;

S2, flattening the laser beam 117 into a parallel beam through the action of the lens 116, and then guiding the flattened laser beam into the optical element assembly 1110 via the optical path reflecting mirror 119;

S3, performing optical path correction on the laser beam 117 by the optical element assembly 1110;

S4, passing the laser beam 117 through the main optical path focusing lens 1112 via a central opening of the semi-enveloping controllable-angle total reflection mirror 113; simultaneously, allowing a refracted beam and a reflected beam to pass through a refraction-reflection beam collection optical path composed of a plurality of total reflection mirrors 112 and the semi-enveloping controllable-angle total reflection mirror 113, so as to perform total reflection collection on the refracted beam and the reflected beam;

S5, adjusting, by the laser beam of the main optical path 1111, an incident laser beam so that a focus thereof acts on a surface of the workpiece 1114; and

S6, using the secondary optical path focusing lens 1113 to adjust the refraction-reflection laser beam, causing a focus of the refraction-reflection laser beam to act on the surface of the workpiece 1114, and ensuring the focus of the refraction-reflection laser beam is located ahead of the focus of the main optical path laser beam.

In this embodiment, in the step S4, when the laser beam 117 passes through the main optical path focusing lens 1112, the laser beam 117 undergoes refraction and reflection phenomena, weakening the energy of the laser beam 117; in the step S4, the patch sensors on the semi-enveloping controllable-angle total reflection mirror 113 and the total reflection mirror 112 detect the incoming beam and output parameters of an incident angle thereof; in the step S4, based on the detection data from the patch sensors, the controller 115 controls the angle control mechanism 114 to rotate the positions of the semi-enveloping controllable-angle total reflection mirror 113 and the total reflection mirror 112, thereby focusing the refraction-reflection beam onto the secondary optical path focusing lens 1113; in the step S6, the focus of the secondary optical path 111 is used to pre-treat the workpiece 1114, and the focal energy of the secondary optical path 111 can reach 10%-15% of the focal energy of the main optical path 1111. By disposing the controller 115 and the secondary optical path focusing lens 1113, based on detection data from the patch sensors, the controller 115 controls the angle control mechanism 114 to rotate positions of the semi-enveloping controllable-angle total reflection mirror 113 and the total reflection mirror 112, thereby focusing the refraction-reflection beam onto the secondary optical path focusing lens 1113. Then, through the action of the secondary optical path focusing lens 1113, a focus of the refraction-reflection laser beam acts on the workpiece 1114. According to existing lens refraction and reflection performance, focal energy of the secondary optical path 111 can reach about 10%-15% of focal energy of the main optical path 1111. At this time, the focus of the secondary optical path 111 is used to pre-treat the workpiece 1114, causing local melting and surface modification on the surface of the workpiece 1114, increasing surface roughness thereof, reducing reflection of the laser beam during main optical path processing, further increasing absorption of laser beam energy in a processing region, thereby improving material removal rate.

### Working Principle

In the disclosure, through the synergistic action of multiple components including a take-up reel, an optical fiber cable tray, a take-up directional reel, and a balancer, the laser beam 117 within the optical fiber 118 is introduced to the starting point of the internal optical path of the laser; the laser beam 117, through the action of the lens 116, is flattened into a parallel beam, and is then guided into the optical element assembly 1110 via the optical path reflecting mirror 119; the optical element assembly 1110 performs optical path correction on the laser beam 117; the laser beam 117 passes through the main optical path focusing lens 1112 via a central opening of the semi-enveloping controllable-angle total reflection mirror 113; simultaneously, a refracted beam and a reflected beam pass through a refraction-reflection beam collection optical path composed of a plurality of total reflection mirrors 112 and the semi-enveloping controllable-angle total reflection mirror 113, so as to perform total reflection collection on the refracted beam and the reflected beam; the laser beam of the main optical path 1111 adjusts an incident laser beam so that a focus thereof acts on the surface of the workpiece 1114; the secondary optical path focusing lens 1113 adjusts the refraction-reflection laser beam so that a focus thereof acts on the surface of the workpiece 1114, and ensures that the focus thereof is positioned ahead of the focus of the main optical path laser beam.

Through the total reflection mirror sheets, the laser light reflected and refracted by each lens is collected, thereby improving energy utilization efficiency, reducing absorption of laser energy by internal components of the laser, and decreasing heat generation; simultaneously, the collected laser light is converged and guided to the secondary optical path 111 to pre-treat the surface of the workpiece 1114, thereby reducing reflection from the workpiece surface and increasing an energy concentration rate of a main optical path spot. According to the detection data from the patch sensors, the controller 115 controls the angle control mechanism 114 to rotate the positions of the semi-enveloping controllable-angle total reflection mirror 113 and the total reflection mirror 112, thereby focusing the refraction-reflection beam onto the secondary optical path focusing lens 1113; then, through the action of the secondary optical path focusing lens 1113, the focus of the refraction-reflection laser beam acts on the workpiece 1114; according to existing lens refraction and reflection performance, the focal energy of the secondary optical path 111 can reach about 10%-15% of the focal energy of the main optical path 1111. At this time, the focus of the secondary optical path 111 is used to pre-treat the workpiece 1114, causing local melting and surface modification on the surface of the workpiece 1114, increasing the surface roughness thereof, reducing the reflection of the laser beam during processing by the main optical path 1111, further increasing the absorption of laser beam energy in the processing region, thereby improving the material removal rate.

Any technical solution utilizing the technical solution described in the present disclosure, or any similar technical solution devised by a person skilled in the art inspired by the technical solution of the present disclosure to achieve the above technical effects, falls within the protection scope of the present disclosure.

1. A dual-optical-path cutting system based on a refraction-reflection laser beam collection system, comprising a lens (116), a laser beam (117), an optical fiber (118), an optical path reflecting mirror (119), an optical element assembly (1110), a main optical path (1111), a main optical path focusing lens (1112), and a workpiece (1114), wherein: the lens (116) is disposed on an optical path of the laser beam (117) emitted from the optical fiber (118); the optical path reflecting mirror (119) is disposed on a side of the lens (116) facing away from the optical fiber (118); the workpiece (1114) is disposed on an optical path of the optical path reflecting mirror (119); the main optical path focusing lens (1112) is installed between the workpiece (1114) and the optical path reflecting mirror (119); the optical element assembly (1110) is installed between the optical path reflecting mirror (119) and the main optical path focusing lens (1112); the main optical path (1111) is an optical path of the laser beam (117) processed through the lens (116), the optical path reflecting mirror (119), the optical element assembly (1110), and the main optical path focusing lens (1112);
further comprising a secondary optical path (111), a total reflection mirror (112), a semi-enveloping controllable-angle total reflection mirror (113), an angle control mechanism (114), a controller (115), and a secondary optical path focusing lens (1113), wherein: the semi-enveloping controllable-angle total reflection mirror (113) is installed on two sides of the main optical path focusing lens (1112); the controller (115) is connected to the semi-enveloping controllable-angle total reflection mirror (113) via the angle control mechanism (114); a light beam emitted from the semi-enveloping controllable-angle total reflection mirror (113) is reflected by the total reflection mirror (112) onto the secondary optical path focusing lens (1113); the secondary optical path (111) is an optical path of the collected light beam processed through the total reflection mirror (112) and the secondary optical path focusing lens (1113).

2. The dual-optical-path cutting system based on the refraction-reflection laser beam collection system according to claim 1, wherein the optical element assembly (1110) comprises a reflecting mirror, a focusing mirror, a half-wave plate, a polarization beam splitter, a timer shutter, a spatial light modulator, and a convex lens; the reflecting mirror, the focusing mirror, the half-wave plate, the polarization beam splitter, the timer shutter, the spatial light modulator, and the convex lens perform optical path correction on the laser beam (117).

3. The dual-optical-path cutting system based on the refraction-reflection laser beam collection system according to claim 2, wherein the semi-enveloping controllable-angle total reflection mirror (113) and the total reflection mirror (112) are each composed of a plurality of total reflection mirror sheets, and each total reflection mirror sheet is connected to the angle control mechanism (114).

4. The dual-optical-path cutting system based on the refraction-reflection laser beam collection system according to claim 3, wherein the semi-enveloping controllable-angle total reflection mirror (113) and the total reflection mirror (112) are each provided with a patch sensor.

5. The dual-optical-path cutting system based on the refraction-reflection laser beam collection system according to claim 3, wherein the patch sensor is connected to the controller (115).

6. A dual-optical-path cutting method based on a refraction-reflection laser beam collection system, using the dual-optical-path cutting system based on the refraction-reflection laser beam collection system according to claim 5, comprising the following steps:
S1, introducing the laser beam (117) within the optical fiber (118) to the starting point of the internal optical path of the laser through the synergistic action of multiple components including a take-up reel, an optical fiber cable tray, a take-up directional reel, and a balancer;
S2, flattening the laser beam (117) into a parallel beam through the action of the lens (116), and then guiding the flattened laser beam into the optical element assembly (1110) via the optical path reflecting mirror (119);
S3, performing optical path correction on the laser beam (117) by the optical element assembly (1110);
S4, passing the laser beam (117) through the main optical path focusing lens (1112) via a central opening of the semi-enveloping controllable-angle total reflection mirror (113); simultaneously, allowing a refracted beam and a reflected beam to pass through a refraction-reflection beam collection optical path composed of a plurality of total reflection mirrors (112) and the semi-enveloping controllable-angle total reflection mirror (113), so as to perform total reflection collection on the refracted beam and the reflected beam;
S5, adjusting an incident laser beam by the laser beam of the main optical path (1111), causing a focus thereof to act on a surface of the workpiece (1114); and
S6, using the secondary optical path focusing lens (1113) to adjust the refraction-reflection laser beam, causing a focus of the refraction-reflection laser beam to act on the surface of the workpiece (1114), and ensuring the focus of the refraction-reflection laser beam is located ahead of the focus of the main optical path laser beam.

7. The dual-optical-path cutting method based on the refraction-reflection laser beam collection system according to claim 6, wherein in the step S4, when the laser beam (117) passes through the main optical path focusing lens (1112), the laser beam (117) undergoes refraction and reflection phenomena, weakening the energy of the laser beam (117).

8. The dual-optical-path cutting method based on the refraction-reflection laser beam collection system according to claim 6, wherein in the step S4, the patch sensors on the semi-enveloping controllable-angle total reflection mirror (113) and the total reflection mirror (112) detect the incoming beam and output parameters of an incident angle of the incoming beam.

9. The dual-optical-path cutting method based on the refraction-reflection laser beam collection system according to claim 6, wherein in the step S4, based on the detection data from the patch sensors, the controller (115) controls the angle control mechanism (114) to rotate the positions of the semi-enveloping controllable-angle total reflection mirror (113) and the total reflection mirror (112), thereby focusing the refraction-reflection beam onto the secondary optical path focusing lens (1113).

10. The dual-optical-path cutting method based on the refraction-reflection laser beam collection system according to claim 6, wherein in the step S6, the focus of the secondary optical path (111) is used to pre-treat the workpiece (1114), and the focal energy of the secondary optical path (111) can reach 10%-15% of the focal energy of the main optical path (1111).
